(19) United States
(12) Patent Application Publication
(10) Pub. No.: US 2013/0092234 A1
(43) Pub. Date: Apr. 18, 2013

(54) Concentrator Array

(71) Applicant: Alonso Marquez, Palmerston (AU)

(72) Inventor: Alonso Marquez, Palmerston (AU)

(21) Appl. No.: 13/652,193

(22) Filed: Oct. 15, 2012

(30) Foreign Application Priority Data
Oct. 17, 2011 (AU) 2011904285

(51) Int. Cl. F24J 2/46; H01L 31/0232

(52) U.S. Cl. 136/259; 126/600

(57) ABSTRACT

A concentrator array is disclosed that includes a plurality of concentrators. Each concentrator has an inlet end to collect rays from a source and an output end to direct the rays at a target. A plurality of rotators are operatively associated with the plurality of concentrators to move the plurality of concentrators so that the rays are focused on the target.

### CROSS REFERENCE TO RELATED APPLICATIONS

Not applicable.

### REFERENCE REGARDING FEDERALLY SPONSORED RESEARCH OR DEVELOPMENT

Not applicable.

### SEQUENTIAL LISTING

Not applicable.

### BACKGROUND OF THE INVENTION

1. Field of the Background

The present invention relates to concentrators and in particular to a concentrator array capable of concentrating waves of various types towards a central point to be utilized for various functions such as energy generation.

2. Description of the Background

Concentrators are known and have been used for some time. Concentrating solar power by using mirrors or lenses to concentrate a large area of sunlight or solar thermal energy onto a target site has been a common place use. Electrical power can then be produced through concentrated energy by driving an engine or turbine connected to electrical power generators.

Typical concentrators include parabolic troughs, dish stirlings, concentrating linear Fresnel reflectors and solar power towers. All these devices typically consist of reflecting concentrated light onto a receiver positioned along the reflectors focal line. At the focal line there is typically a container of some sort filled with a working fluid. The advantage of such devices is that the power source being used (the sun) is free.

The main problem with such concentrators to date is the significant expenditure required to install a concentrator array plant, the large surface area required, and the efficiency of the concentrators used. Though typically originally glass mirrors were used in the concentrators these days silver polymer sheets or the like can provide the same performance at a much lower cost and weight. Use of several films using several layers of polymers with an internal layer of silver or the like has also been suggested.

There is however a need to improve flux densities in radiant energy applications by gathering direct and diffused light and redirecting the rays so that they are compressed into dense, directionally focused rays to suit a particular application.

There is also a need for a very low maintenance non-tracking concentrator, which is simple to install and works automatically with little human intervention. For example, by using a simple and cheap tracking element. Existing tracking systems have low tolerance for error. By eliminating elaborate tracking methods you allow for cheap concentration arrays.

The full spectrum of daylight during the year can encompass a wide range of positions and intensities. It is therefore desirable to capture light from a customisable area. However, due to the trade-off between concentration and the reception area, a concentrator array should tend to capture light from higher intensity positions to maximize returns.

Although the sun is currently used for water heating, current water heating systems do not concentrate to any degree, they utilize heat retention systems to capture incoming heat. It is naturally inefficient since each square inch can only capture that heat which traditionally falls within it. With concentration, these systems can achieve much higher levels of efficiency and provide much needed improved functionality in colder environments.

It is an object of the present invention to substantially overcome or at least ameliorate one or more of the disadvantages of the prior art, or to at least provide a useful alternative.

### SUMMARY OF THE INVENTION

According to one embodiment, a concentrator array includes a plurality of concentrators. Each concentrator has an inlet end to collect rays from a source and an output end to direct the rays at a target. A plurality of rotators are operatively associated with the plurality of concentrators to move the plurality of concentrators so that the rays are focused on the target.

In one embodiment, the concentrators are located in series. In another embodiment, the array includes one or more wave pipes to further direct the rays at the target. In a different embodiment, the target includes a concentrator. In another embodiment, the target is one or more solar cells. In yet a different embodiment, each concentrator includes means to dissipate unwanted heat from the concentrator. In a different embodiment, the rays are sunlight, x-rays, radio waves or microwaves. In a different embodiment, the array includes tracking means to track a source of the rays, the means adapted to move the rotators to move the concentrators to capture rays from the source. In still a different embodiment, the array includes one or more collimators. In another embodiment, the array includes a fluid operatively associated with the concentrators. In an additional embodiment, the array includes one or more feed aggregators. In a different embodiment, an aggregator array is operatively associated with the concentrator array. In another embodiment, a rotation angle of the concentrators is an angle between a plane of the rays entering the input end and the rays exiting the output end, the cosine of the rotation angle being lower or equal to the inverse of the level of concentration selected by a user. In a different embodiment, there is disclosed a panel which includes one or more concentrator arrays according to the above aspect.

### BRIEF DESCRIPTION OF THE DRAWINGS

Other aspects and advantages of the present invention will become apparent upon reading the following detailed description and upon reference to the drawings in which:

FIG. 1 is a schematic view of a concentrator showing the relation between input and output planes;

FIG. 2A is a top plan view of an array of concentrators;

FIG. 2B is a side elevational view of an array of concentrators;

FIG. 3 is a side elevational view of a rotator array attached to a concentrator array;

FIG. 4 is side elevational view of an aggregator array attached to a rotator array;

FIG. 5 is a side elevational view of a further aggregator array attached to a rotator array;

FIG. 6 is a schematic view of eleven aggregators and rotators aimed at a single target;

FIG. 7 is a schematic view of a wedge absorber and a corresponding concentrator obtained by splitting it in half;

FIG. 8 is a side isometric view of two unilateral concentrators;

FIG. 9 is a side isometric view of a bilateral concentrator; and

FIG. 10 is an isometric view of a wall concentrator.

### DETAILED DESCRIPTION OF THE INVENTION

Referring to the drawings, a concentrator array 1 is disclosed that includes a plurality of concentrators 2 each concentrator 2 having an inlet end 3 (with angle of acceptance Theta^{o}) to collect rays 20 from a source (not shown) and an outlet end 4 (with angle of acceptance Thetaⁱ) to direct the rays at a target 5. The concentrator array 1 includes means 6 such as a rotor or rotator to move each concentrator 2 so that the rays are focused on the target 5. An aggregator 7 could also be attached to the end of the rotor 6 to help direct the rays towards the target 5.

The present invention at least in a preferred form is directed towards flattening and making a more compact use of traditional concentration techniques in a simple design that is easy to build and accessible to virtually anyone.

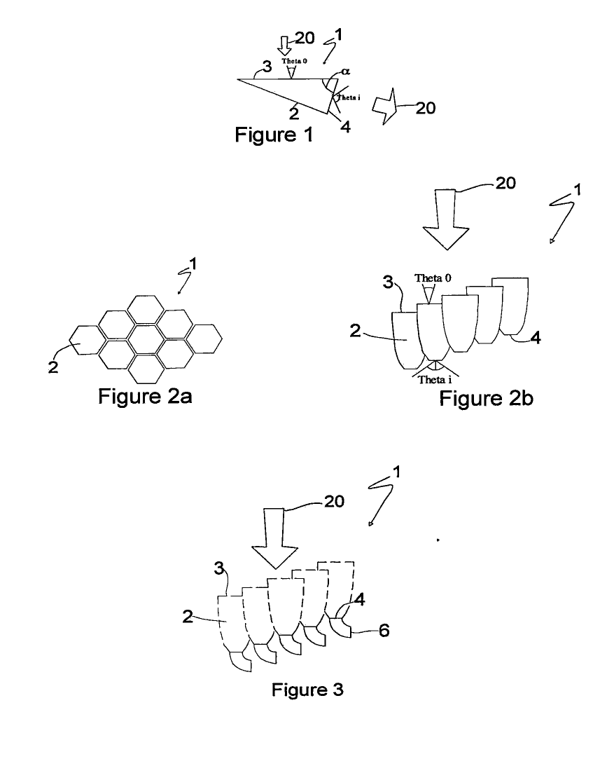

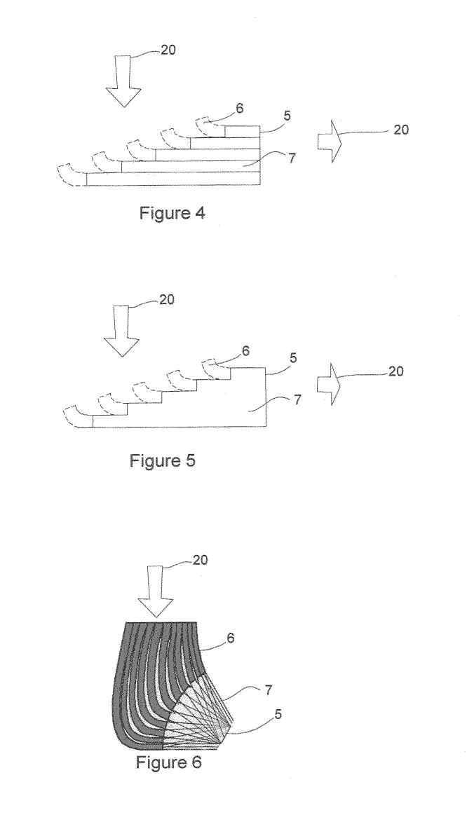

As shown in FIG. 1, a series of concentrators 2 (e.g., non imaging concentrators) with angle rotators 6 and wave pipes (not shown) are combined so that the cosine of the rotation angle a (angle between the input and output planes) is lower or equal to the inverse of the level of concentration desired.

To achieve a result the combination of concentrators 2, rotators 6 and wave pipes (not shown) in three phases needs to provide a unified output to the target 5.

The use of a series of concentrators 2 (one or two dimensional) potentially includes a rotator component such that the union of all concentrators 2 input covers most, or all, of the input radiation area that it is intended to concentrate. Optionally, concentrators 2 could be placed at different levels to avoid a disparity in the length of the rotator component. FIG. 2 shows different perspectives of an array 1 of two dimensional concentrators 2.

A rotator phase (if previous phase does not provide a rotation with angle α or larger) is utilised to take the output 4 of each of the concentrators 2 (with angle of acceptance Thetaⁱ) as input and generate an output that would normally be with the same angle of acceptance but with the rotation desired.

Zero or more angle rotators 6 or similar devices connected to the output 4 from the concentrators 2 can be used. This may be fine pipes such as optic fibre with small bends, or specialised angle rotators or the like. The input of each rotator 6 must exactly match the output 4 of one or more concentrators 2 from the previous phase. FIG. 3 shows an example of an array 1 of angle rotators 6. In a similar way to the concentrators 2, rotators 6 could be placed at different levels to better match the aggregators 7 that will capture their output.

Also, zero or more pipes or slates or any wave transmitting material can be utilised to funnel away the wave to the common target 5. At the same stage from the input to the output of the aggregator 7, they might partially overlap or join other aggregators 7 to become a common one. The input of each aggregator 7 will exactly match the output of one or more of the rotators 6 from the previous phase (or from the concentrators 2 if rotator phase is not required). The funnelling can be carried out by plastic fibres/fibre optics/tubes/systems or the like. The use of water with additives within a tube made of glass/plastic can achieve this same effect and provide a source of heat dissipation/cooling.

As shown in FIG. 5 an alternative embodiment would combine several or all of the aggregators 7 in a more complex aggregator 7 with equivalent optical properties. This complex aggregator could be made at a very low cost by using glass/plastic for the external shape and a filling of suitable low cost materials (e.g. water with additives such as glycerine to increase its refraction index and reduce its freezing point, white mineral oil, etc.).

A second solution (that might be combined with the first one) is to overlap the output of rotators 6 and aggregators 7 (phase 2 and 3 above) to achieve a higher flux density. When using a small acceptance angle, rotators 6 and aggregators 7 could be easily approximated by very common and low cost geometric forms such as bent tubes, sheets or the like. These concentrator arrays 1 can also be of use by themselves for specific applications due to their very low cost components. For example, use rotators 6 and aggregators 7 can produce a concentration of almost 9 times. This second variation of the concentrator would also be quite close to an ideal concentrator array 1 if the rotator 6 is ideal (there are no losses in the rotators/aggregators phases) and the number of components is high enough. In practical terms, ten or more rotators 6/aggregators 7 will provide a sensible approximation to an ideal concentrator array 1.

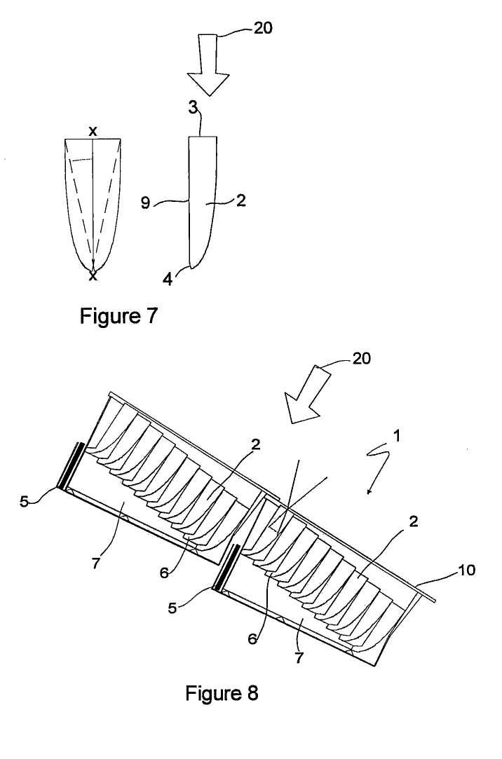

Still another variation is shown in FIG. 7 where specialised concentrators contain in themselves a rotator component. Examples of this type of concentrator 2 include the halved wedged absorber shown in FIG. 1 having a Theta^{o}/Thetaⁱ variation of this design (with exit angle Thetaⁱ instead of Pi/2). The halved wedged concentrator 9 is obtained by splitting the wedged absorber at its optical axis/symmetrical axis XX. The adaptation of the Theta^{o}/Thetaⁱ concept is done to make sure that Total Internal Refraction (TIR) is achieved. It might also be truncated to reduce its size.

The above embodiments could be applied to concentrate the full area of the input or only one dimension at a time. It may be convenient to take the output 4 of the first concentrator 2 and use it as input 8 for a second stage concentrator 2 (normally far smaller than the first one). This arrangement is particularly useful when the first concentration was only applied in one dimension. In this particular case, the second concentrator 2 could apply the concentration in the dimension orthogonal to the one where the concentration was applied in the first stage. Multiple stages could be used to overcome limitations in the output angle brought about by the use of TIR in each of the subcomponents.

The resulting concentrator array 1 will be ideal (or close to) in the measure that the micro concentrators 2 and rotators 6 are ideal (or close to) and all components have very small optical loses (or none) and the output of each phase closely/exactly matches the input 3 of the next. The output angle of each phase matches the input angle of the next. The input/output angle and the level of concentration of the concentrator 2 will be the average of the input/output angle and level of concentration of the component concentrators.

For practical purposes all components will need to be engineered to minimise loses by reflection and refraction.

The volume/size of the combination of a concentrator 2 and a rotator 6 is linearly dependent on their number. Therefore, phase 1 and 2 of the concentrator array 1 can be downsized to almost infinitesimally small sizes (the figure being geometrically simple allows for a simple manufacturing process) which can then be combined in sequence (taking up minimal space). Phase 3 (aggregator) cannot be reduced in a similar way by increasing the number of components but their size/volume is still far less than alternative concentrator solutions.

The complexity of building Phase 1 and 2 would be quite low in the case of a one dimensional concentrator array 1 because the combination of both phases can be made in a planar surface. Techniques such as acrylic cutting could be applied to minimise the manufacturing cost. Phase 3 involves normally quite simple geometrical figures that could be easily built using standard plastic manufacturing processes.

The cost/weight created by the aggregator component should be considered. Phase 1 and 2 components could be easily reduced in cost/weight by increasing the number of components. Phase 3 (aggregation phase) can be easily reduced in cost by using the complex aggregator embodiment using a suitable low cost filling material. Still another option is to use air as the complex aggregator filling material. This solution will be very convenient in cost/weight but will incur a certain loss in its concentration due to reflection loses in the interface between rotators and aggregators.

The dissipation/filtering of the heat capture by the concentration process or generated as a by-product of the Photovoltaic energy generation process. The heating of the targets (solar cells) is a source of inefficiency and it normally becomes relevant at levels of concentration greater than 3 times.

A reflective coating on the concentration phase could be used to reflect any infrared. Also the aggregator 7 could play the dual purpose of heat dissipation. For example, most of the heat could be captured and dissipated by using a complex aggregator 7 using a suitable filling material to capture the heat and channel it to external radiators (not shown) placed in a way that does not interfere with the incoming radiation. An example of this may include water (coupled with other compounds), transmitting electromagnetic waves whilst dissipating heat from the cells.

A further embodiment concentrates beams that approach from remote sources (e.g. the sun). It combines a series of half Theta^{o}/Thetaⁱ wedge truncated concentrators 9 corresponding to the concentrator phase, with angle rotators 6 and a complex aggregator 7 that funnel the light to the solar cell/panel 5.

FIG. 8 shows a lateral view of two Unilateral Concentrator Arrays 1 placed in series, each one with 10 concentrators 2 (about 19°/55°) and angle rotators 6. Active optical components made from glass or plastic with a refractive index around 1.49 (e.g., acrylic) can be used with solar cell 5 and an encasing box 10 and transparent lid of the concentrator (made from a stronger material such as polycarbonate). This particular example has an acceptance angle of almost 19° and provides a maximum concentration of about 3.6× (3.2× the energy generated by the standalone solar cell in average), making it suitable for static applications in the residential sector. It could use standards solar cells 5 and the aggregator 7 could be filled with water, mineral oil or the like to minimize cost.

A variation of this design using a large number of components (e.g., 50 concentrators) and smaller solar cells (about 5 cm width) would be suitable for residential applications as a solar tile or a replacement of standard solar panels or the like.

This should reduce the cost of energy per watt by concentrating light on the left extreme. By increasing the number of concentrators/angle rotators, the concentrator/rotator phases can be resized and shrunk to minute proportions creating a virtually flat surface. The design may be replicated successively to achieve concentration in multiple dimensions. Any material that allows for the transmission of waves in turn may perform the concentration. Examples include, but are not limited to, glass, plastics, water and combinations of materials. The transmission (funnelling) may be carried out through means other than plastic, or solids (even air). It is also translucent to the early morning and late afternoon light.

This could be replicated with different input and output acceptance angles, number of components, using a series of non-complex aggregators 7 instead of a complex one or using other types of concentrators 2 and angle rotators 6 such as Theta^{o}/Thetaⁱ and using other solar energy capture mediums (e.g. water for solar water heating).

Another example of a Bilateral Concentrator Array concentrates beams that approach from remote sources (e.g. the sun). It combines 104 half/Thetaⁱ wedge truncated concentrators 2 corresponding to the concentrator phase, with the same number of angle rotators 6 and two complex aggregators 7 that funnel the light to both sides of a bifacial solar cell/panel 5.

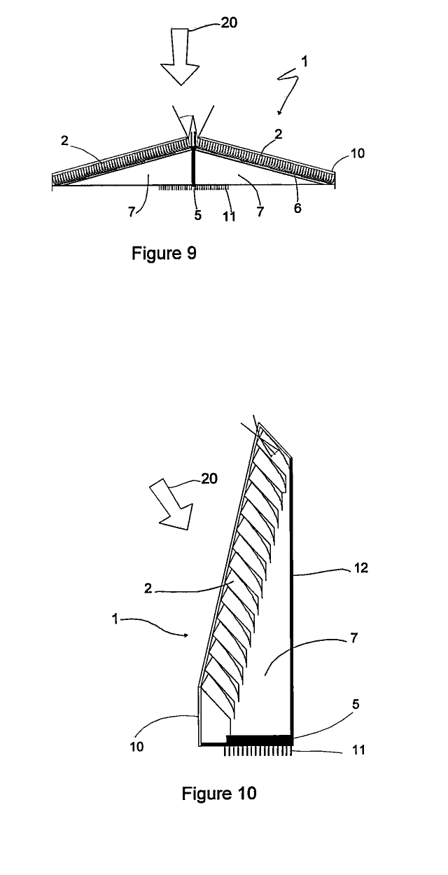

FIG. 9 shows a lateral view of this Bilateral Concentrator Array 1 with 104 concentrators (about 19°/55°) and rotators 6. Active optical components can be made from glass or plastic with a refractive index around 1.49 (e.g. acrylic) and directed to a bifacial solar cell/panel 5. An encasing box 10 can be used and the two complex aggregator components (both made from a transparent but stronger material such as polycarbonate). A passive cooling component 11 with fins designed to capture and dissipate the heat from the solar cell 5 and the aggregator filling medium (that it is also playing a cooling role) could be utilised. The top cooling component also plays the role of removable lid of the array 1 enabling the easy maintenance/replacement of the solar cells/panel 5 when required. The complex aggregator 7 could be filled with filling materials (e.g. mineral oil) to minimize cost.

This particular example has an acceptance angle of about 30° and provides a maximum concentration of about 6.7× (5.9× the energy generated by one side of a standalone bifacial solar cell in average), making it suitable for static applications in the industrial sector. The input planes of each side of the concentrator array 1 have been oriented to slightly different angles to smooth the concentration peak and reduce losses through overheating of the solar cell/panel 5. The top two sides of the concentrator array cover play a similar role by bending the light in different directions, increasing the acceptance angle of the concentrator.

The high level of average concentration will create savings of about 5× in the cost of the solar cells/panel required; making this concentrator array 1 ideal for high scale production of solar energy (e.g. solar farms).

Applying the generic idea behind the model above, concentration may be applied on a central pivot (not shown). This pivot may be solar panels, or tubes (to heat liquids/gases) or anything else that may benefit from concentration on multiples sides.

Referring to FIG. 10, there is shown a concentrator array 1 that combines a series of half Theta^{o}/Thetaⁱ wedge truncated concentrators 2 corresponding to the concentrator phase and a complex aggregator 7 that funnels the light to the solar cell/panel 5. This embodiment does not require angle rotators because the selected concentrators 2 provide the rotation required. This embodiment is designed to be used on the wall 12 of a building.

The wall concentrators of FIG. 10 shows 15 concentrators 2 (about 19°/55°). Active optical components are made from glass or plastic with a refractive index about 1.49 (e.g. acrylic) and there is a bifacial solar cell/panel 5 and an encasing box 10 and the complex aggregator components (both made from a transparent but stronger material such as polycarbonate). A passive cooling component with fins 11 designed to capture the heat from the solar cell 5 and the aggregator filling medium (that it is also playing a cooling role) is provided.

This particular example has an acceptance angle of almost 19° and provides a maximum concentration of about 3.6× (3.2× the energy generated by the standalone solar cell in average), making it suitable for static applications in building and factories. It could use standard solar cells and the aggregator 7 could be filled with filling materials such as water with additives or mineral oil to minimize cost. The angle of acceptance is about 19° though it is in practice a bit more because of the use of truncated concentrators 2.

This example displays the application of the general design on vertical surfaces 12. Since the angle of acceptance may be manipulated by design quiet readily, these can be geared to function very efficiently at certain times of the day, and may be placed on walls 12 or angled surfaces at any height. They may also be designed to be aesthetically pleasing.

This embodiment is intended to reduce the cost of energy per watt by concentrating light on the bottom extreme. By increasing the number of concentrators/angle rotators, the concentrator/rotator phase components can be resized and shrunk to minute proportions creating a virtually flat surface. The design may be replicated successively to achieve concentration in multiple dimensions. Any material that allows for the transmission of waves in turn may perform the concentration. Examples include, but are not limited to, glass, plastics, water and combinations of materials. The transmission (funnelling) may be carried out through means such as plastics, solids, liquids or gases (e.g., air).

The aggregator model outlines a generic design that could be replicated with different input and output acceptance angles, number of components, use of a series of non-complex aggregators instead of a single complex one and/or and using other solar energy capture mediums (e.g. water for solar water heating).

### INDUSTRIAL APPLICABILITY

Numerous modifications will be apparent to those skilled in the art in view of the foregoing description. Accordingly, this description is to be construed as illustrative only and is presented for the purpose of enabling those skilled in the art to make and use the invention and to teach the best mode of carrying out same. The exclusive rights to all modifications which come within the scope of the appended claims are reserved.

What is claimed is:

1. A concentrator array, comprising:
a plurality of concentrators, wherein each concentrator has an inlet end to collect rays from a source and an output end to direct the rays at a target; and
a plurality of rotators operatively associated with the plurality of concentrators to move the plurality of concentrators so that the rays are focused on the target.

2. The concentrator array of claim 1, wherein the plurality of concentrators are located in series.

3. The concentrator array of claim 1 further including one or more wave pipes to further direct the rays at the target.

4. The concentrator array of claim 1, wherein the target also includes a concentrator.

5. The concentrator array of claim 1, wherein the target is one or more solar cells.

6. The concentrator array of claim 1, wherein each the concentrator includes means to dissipate unwanted heat from the concentrator.

7. The concentrator array of claim 1, wherein the rays are sunlight, x-rays, radio waves or microwaves.

8. The concentrator array of claim 1 further including tracking means to track a source of the rays, the means adapted to move the plurality of rotators to move the plurality of concentrators to capture rays from the source.

9. The concentrator array of claim 1 further including one or more collimators.

10. The concentrator array of claim 1 further including a fluid operatively associated with the plurality of concentrators.

11. The concentrator array of claim 1 further including one or more feed aggregators.

12. The concentrator array of claim 1, wherein an aggregator array is operatively associated with the concentrator array.

13. The concentrator array of claim 1, wherein a rotation angle of the plurality of concentrators is an angle between a plane of the rays entering the input end and the rays exiting the output end, the cosine of the rotation angle being lower or equal to the inverse of the level of concentration selected by a user.

14. The concentrator array of claim 1, wherein one or more concentrator arrays are provided on a panel.
